(19) United States
(12) Patent Application Publication
(10) Pub. No.: US 2013/0146785 A1
(43) Pub. Date: Jun. 13, 2013

(54) SUPPORT, LITHOGRAPHIC APPARATUS AND DEVICE MANUFACTURING METHOD

(71) Applicants: Noud Jan GILISSEN, 's-Gravenzande (NL); Martinus Agnes Willem CUIJPERS, Veldhoven (NL); Menno FIEN, Tilburg (NL); Anko Jozef Cornelus SIJBEN, Veghel (NL); Martin Frans Pierre SMEETS, Veldhoven (NL)

(72) Inventors: Noud Jan GILISSEN, 's-Gravenzande (NL); Martinus Agnes Willem CUIJPERS, Veldhoven (NL); Menno FIEN, Tilburg (NL); Anko Jozef Cornelus SIJBEN, Veghel (NL); Martin Frans Pierre SMEETS, Veldhoven (NL)

(73) Assignee: ASML NETHERLANDS B.V., Veldhoven (NL)

(21) Appl. No.: 13/685,502

(22) Filed: Nov. 26, 2012

Related U.S. Application Data
(60) Provisional application No. 61/565,872, filed on Dec. 1, 2011.

(51) Int. Cl. G03F 7/09

(52) U.S. Cl. CPC G03F 7/09
USPC 250/453.11

(57) ABSTRACT

A support for an object having a support surface configured to support the object; wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.

This application claims priority and benefit under 35 U.S.C. §119(e) to U.S. Provisional Patent Application No. 61/565,872, filed on Dec. 1, 2011. The content of that application is incorporated herein in its entirety by reference.

### FIELD

The present invention relates to a support, a lithographic apparatus and a device manufacturing method.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

The machine may be one in which a liquid having a relatively high refractive index, e.g. water, fills a space between the final element of the projection system and the substrate. In an embodiment, the liquid is distilled water, although another liquid can be used. Another fluid may be suitable, particularly a wetting fluid, an incompressible fluid and/or a fluid with higher refractive index than air, desirably a higher refractive index than water. Fluids excluding gases are particularly desirable. The point of this is to enable imaging of smaller features since the exposure radiation will have a shorter wavelength in the liquid. (The effect of the liquid may also be regarded as increasing the effective numerical aperture (NA) of the system and also increasing the depth of focus.) Other immersion liquids have been proposed, including water with solid particles (e.g. quartz) suspended therein, or a liquid with a nano-particle suspension (e.g. particles with a maximum dimension of up to 10 nm). The suspended particles may or may not have a similar or the same refractive index as the liquid in which they are suspended. Other liquids which may be suitable include a hydrocarbon, such as an aromatic, a fluorohydrocarbon, and/or an aqueous solution.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes a programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, and the like.

As disclosed in PCT patent application publication no. WO 2010/032224, hereby incorporated in its entirety by reference, instead of a conventional mask a modulator may be configured to expose an exposure area of the substrate to a plurality of beams modulated according to a desired pattern. The projection system may be configured to project the modulated beams onto the substrate and may comprise an array of lenses to receive the plurality of beams. The projection system may be configured to move the array of lenses with respect to the modulator during exposure of the exposure area.

The lithographic apparatus may be an extreme ultraviolate (EUV) radiation apparatus which uses extreme ultra violet light (e.g. having a wavelength of in the range of about 5-20 nm).

### SUMMARY

In an embodiment of a lithographic apparatus, a substrate is loaded on a support surface of a substrate table by a robot which holds the substrate at the bottom side of the substrate. To facilitate loading of the substrate on a substantially horizontal support surface, a plurality of pins (hereinafter “e-pins”) are provided in the substrate table. For example, three e-pins may be provided. The e-pins are movable between an extended position, wherein the upper ends of the e-pins extend above the substrate table, and a retracted position, wherein the upper ends of the e-pins are retracted in the substrate table.

During the loading of the substrate on the substrate table, the robot loads the substrate on the e-pins in the extended position. Since the substrate is received on the e-pins extending above the support surface, the robot can be withdrawn leaving the substrate on the e-pins. Then, the e-pins can be moved to the retracted position to place the substrate on the support surface.

The shape of the substrate during the loading sequence is defined by the gravity sag of the substrate. Other influences, such as the influence of a gas (e.g., air) flow below the substrate, may also have an effect on the shape of the substrate. There is limited freedom to manipulate the final substrate shape while it touches the substrate table.

Substrates with increasing sizes are to be handled in a lithographic apparatus. Presently substrate sizes having widths up to 300 mm are used in lithographic processes. It is desirable to increase substrate widths (e.g., diameters), for example to a diameter of approximately 450 mm. These larger substrates will have a smaller thickness to width ratio, resulting in a reduced bending stiffness. As a result, the substrates may have a larger gravitational deflection on the e-pins in the extended position, which could inherently lead to larger substrate load grid errors and potentially also overlay errors. Also the e-pins may need to have a larger surface area to support the increased weight of the substrate compared to, for example, a 300 mm diameter substrate and this can lead to a decrease in flatness when the substrate is clamped to the support (because in that state the substrate is not supported above the e-pins).

It is desirable, for example, to provide a support in which measures are taken to reduce bending of a substrate during loading.

According to an aspect of the invention, there is provided a support for an object, comprising: a support surface configured to support the object; wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.

According to an aspect of the invention, there is provided a support for an object, comprising: a support surface configured to support the object; and an elongate moveable part arranged, in plan, to form a side of a multi-sided shape and moveable between a retracted position in which an upper end of the moveable part is adapted to be at or below the plane of a main part of the support surface and an extended position in which the upper end of the moveable part protrudes from the plane of the main part of the support surface.

According to an aspect of the invention, there is provided a device manufacturing method comprising projecting a patterned beam of radiation onto a substrate supported by a support surface, wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 illustrates schematically and in plan a support according to an embodiment;

FIG. 3 illustrates a cross-section through line III of FIG. 2, when in the retracted position;

FIG. 4 illustrates a cross-section through line III of FIG. 2, when in the extended position;

FIG. 5 illustrates a cross-section through line V of FIG. 2;

FIG. 6 is a detail, in plan, of part of the moveable part of the embodiment of FIG. 2;

FIG. 7 illustrates a moveable part of an embodiment; and

FIG. 8 illustrates schematically and in plan a support according to an embodiment.

### DETAILED DESCRIPTION

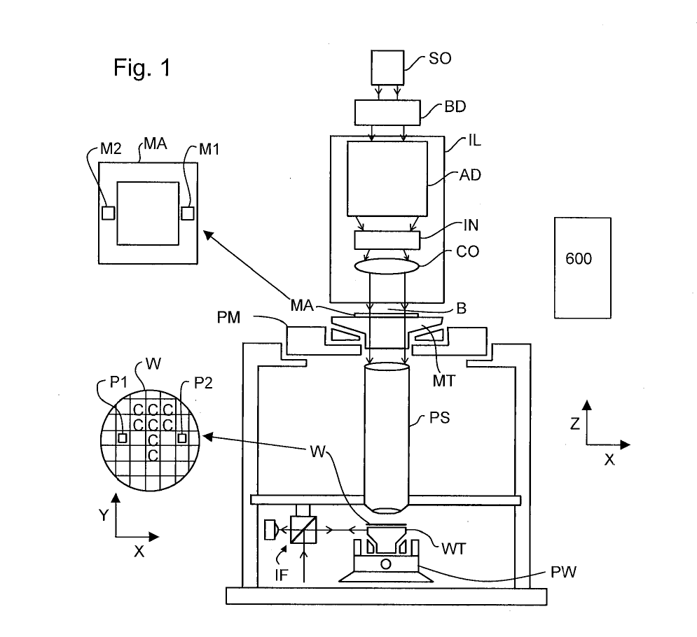

FIG. 1 schematically depicts a lithographic apparatus according to one embodiment of the invention. The apparatus comprises:

an illumination system (illuminator) IL configured to condition a radiation beam B (e.g. UV radiation or DUV radiation).

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WT constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, catadioptric, magnetic, electromagnetic, electrostatic or other types of optical components, or any combination thereof, for directing, shaping, or controlling radiation.

The support structure MT holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two or more tables (or stages or supports), e.g. two or more substrate tables or a combination of one or more substrate tables and one or more sensor or measurement tables. In such “multiple stage” machines the additional tables may be used in parallel, or preparatory steps may be carried out on one or more tables while one or more other tables are being used for exposure. The lithographic apparatus may have two or more patterning devices (or stages or supports) which may be used in parallel in a similar manner to substrate, sensor and/or measurement tables.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not exclusively mean that a structure, such as a substrate, must be submerged in liquid, but rather that liquid can be located between the projection system and the substrate and/or mask during exposure. This may or may not involve a structure, such as a substrate, being submerged in liquid. Reference sign IM shows where apparatus for implementing an immersion technique may be located. Such apparatus may include a supply system for the immersion liquid and a seal member for containing the liquid in the region of interest. Such apparatus may optionally be arranged so that the substrate table is fully covered by the immersion liquid.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section. Similar to the source SO, the illuminator IL may or may not be considered to form part of the lithographic apparatus. For example, the illuminator IL may be an integral part of the lithographic apparatus or may be a separate entity from the lithographic apparatus. In the latter case, the lithographic apparatus may be configured to allow the illuminator IL to be mounted thereon. Optionally, the illuminator IL is detachable and may be separately provided (for example, by the lithographic apparatus manufacturer or another supplier).

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion partly determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, as in other modes, generally a pulsed radiation source is employed and the programmable patterning device is updated as required after each movement of the substrate table WT or in between successive radiation pulses during a scan. This mode of operation can be readily applied to maskless lithography that utilizes a programmable patterning device, such as a programmable mirror array of a type as referred to above.

Combinations and/or variations on the above described modes of use or entirely different modes of use may also be employed.

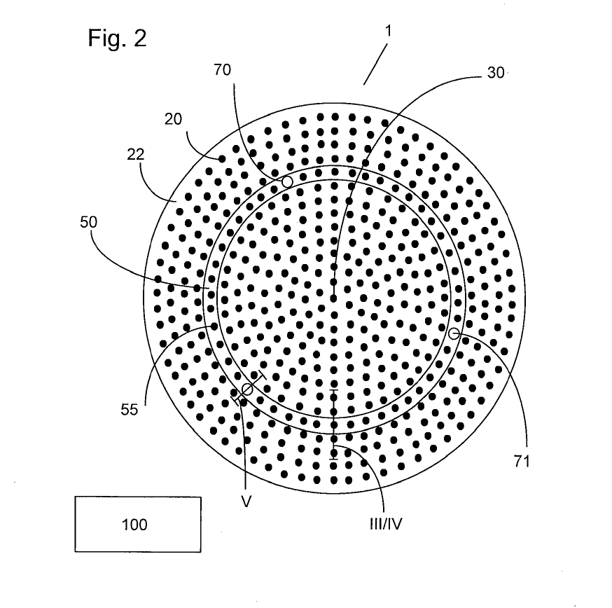

The lithographic apparatus comprises a substrate table WT. An upper part of the substrate table WT is shown in more detail in FIGS. 2-8. FIG. 2 is a plan view of an embodiment of a support 1 of a substrate table WT. The support 1 is configured to support an object, in the case of a lithographic apparatus a substrate W.

The support 1 comprises a support surface 20. The support surface 20 is configured to support the substrate W on the substrate table WT. The support surface 20 may be a flat surface, but may also be defined by a quantity of discrete burls (projections, shown as black dots in FIG. 2) or other objects which extend from a top surface 25 of a main body 22 to a supporting height. Projections may have a pitch of about 1.5-3.0 mm, for example. The top surface of the projections on which the substrate W is supported defines the support surface 20. The projections are present in order to reduce the surface area in contact with the substrate W when the substrate W is placed on the substrate table WT. Each point of contact is a source of potential contamination; reducing the total contact area reduces the chance of contamination.

The support 1 is configured to receive the substrate W at a pre-defined area on the support surface 20. The pre-defined area comprises a center 30. In an embodiment, the center 30 receives the substantial center of the substrate W to be placed on the substrate table WT.

The pre-defined area may be designed to receive a substrate W of relatively large width or size, for example a circular substrate of 450 mm in diameter. Such a large sized substrate W will have a small thickness to width ratio, resulting in a reduced bending stiffness. In an embodiment the pre-defined area may be designed to receive a substrate of a different shape, in plan and/or of a different width or size to a circular substrate of 450 mm diameter.

Particularly for substrates W with a reduced bending stiffness, using only 3 e-pins to lift the substrate W from and onto the supporting surface 20 may lead to surface deformation of the substrate W. Surface deformation induced during loading of the substrate W can lead to more stress in the substrate W when it is clamped to the support 1. Stress in the substrate W when it is clamped to the support 1 can lead to overlay grid errors. During unloading of the substrate W using 3 e-pins, the substrate W is likely to sag at its outer edge. Sagging at an outer edge may lead to more wear of the outer area of the support surface 20 (e.g. the outermost projections) than elsewhere. With time this may lead to focusing errors at the edge of the substrate W.

A solution might be to provide a support 1 with a greater number of e-pins. However, this may lead to more positions in the support 1, in plan, where a support surface 20 in the form of a projection, is not provided (because the substrate W is not supported by the e-pin when clamped to the support 1). This may lead to unflatness of the substrate W when it is clamped to the support 1 and thereby overlay errors.

In the embodiment of FIG. 2 a larger surface area to support the substrate W during transfer to/from the support surface 20 is provided compared to e-pins. In order to reduce the gaps in the support surface 20 (provided by the projections) which would otherwise occur, a moveable part 50 of the support 1 also comprises a surface (the upper end of projections 55) which forms a moveable part of the support surface 20. The moveable part of the support surface 20 is moveable relative to the main body 22 of the support 1. The substrate W is supported by the moveable part of the support surface 20 during unloading and loading of the substrate W. In an embodiment the moveable part of the support surface 20 supports the substrate W during imaging when the substrate W in addition is supported by the remainder of the support surface 20. The remainder of the support surface 20 is a main part of the support surface, which is non-moveable relative to the body 22 of the support 1.

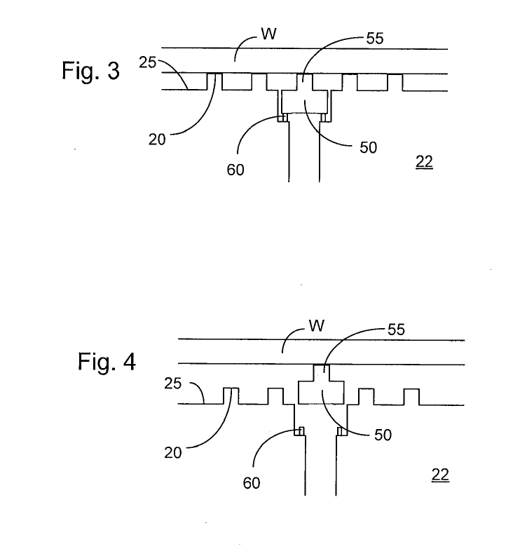

As will be illustrated with reference to FIGS. 3 and 4 the moveable part 50, and therefore the moveable part of the support surface 20, is moveable relative to the main body 22. The moveable part 50 is moveable between a retracted position in which the moveable part of the support surface 20 is at or below the plane of the main part of the support surface 20 and an extended position in which the moveable part of the support surface 20 protrudes from the main part of the support surface 20. In an embodiment in the retracted position the upper end of the projections 55 on the moveable part 50 (i.e. the moveable part of the support surface 20) is substantially in the same plane as the main part (e.g. the remainder) of the support surface 20.

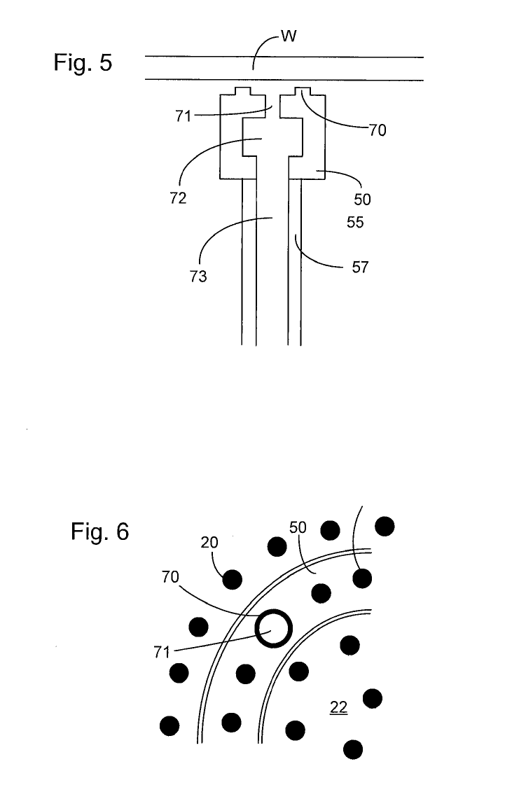

The moveable part 50 in the form of a ring as shown in FIG. 2 may be actuated at three positions equally spaced around its perimeter, for example. Elongate members 57 (shown in FIG. 5) may be used to actuate the moveable part 50 at three discrete locations whereas the moveable part 50 between those discrete locations has a cross section closer to that of a square (without an elongate portion 57, as illustrated in FIG. 5).

As is illustrated in FIG. 2, the moveable part 50 is elongate and arranged, in plan, to form a side of a multi-sided shape. This contrasts to e-pins which are not elongate and do not form sides of a multi-sided shape but rather form corners (of a triangle). In an embodiment the multi-sided shape has at least 8 sides; the nearer to a circle the less deformation of the substrate W which will occur. In an embodiment, such as that of FIG. 2, the moveable part 50 is arranged substantially in the shape of a circle (i.e. an infinitely sided shape). In an embodiment, the moveable part 50 is substantially a gapless complete shape. In an embodiment the moveable part 50 is a ring. An advantage is improved support of the substrate W and less bending during loading/unloading.

In an embodiment the moveable part 50 may comprise more than one moveable part. For example, the moveable part 50 of FIG. 2 could be split into a plurality of separate (optionally individually) moveable segments. In that case each moveable part 50 could be in the shape, in plan, of an arc. Alternatively or additionally, the at least one moveable part may be provided by a plurality of elongate (e.g. linear) moveable parts. The moveable parts 50 may be separated by a gap 59, such as illustrated in FIG. 8 described below.

In an embodiment the radial position of the moveable part 50 relative to the center 30 is chosen for best support of the substrate W and minimum bending by self-weight. In an embodiment the size of area of the support surface 20 inside the moveable part 50 is substantially equal to the size of area of support area 20 outside of the moveable part 50. Some variation from this rule is permitted, the lower the variation the better. For example, the areas inside and outside are within 20% of one another, desirably within 10% or more desirably within 5% of one another.

In an embodiment, in order to reduce or minimize the size and weight of the moveable part 50, the moveable part 50 has a moveable surface which is only one burl (projection 55) wide, as illustrated in FIG. 2. However, a width of a single burl may not be enough to support a substrate W sufficiently and in an embodiment the width (in the radial direction) of the moveable part 50 may be at least two burls (projection 55) wide. In an embodiment the moveable part 50 is five or fewer burls wide in radial direction. With more than five burls the size and weight of the moveable part 50 may become so large that the mechanism to move the moveable part 50 may not be accommodated reasonably in a substrate table WT.

In an embodiment, the area, in plan, of the moveable part 50 compared to the total area, in plan, of the support surface 20 is at least 0.3%, at least 0.5% or at least 0.8%. Thus, the area of support is much larger than that in the art (e-pins in the art have an area of about 0.1% of the area of the support surface 20). As a result deformation may be much less.

In an embodiment, for a 300 mm diameter substrate, the moveable part 50 would have a diameter of 170 mm+/−40 mm. For a 450 mm diameter substrate, the moveable part 50 would have a diameter of about 255 mm+/−50 mm. The moveable part 50 would be about 5 mm wide (typically between 2 and 20 mm wide).

FIG. 3 shows the moveable part 50 in a retracted state in which its upper end (the upper end of projection 55 (or the moveable part of the support surface)) supports the substrate W. The upper end of the moveable part 50 comprises the moveable part of the support surface 20.

In an embodiment a plurality of moveable parts 50 are individually actuatable. In an embodiment a plurality of moveable parts 50 are actuated together. In an embodiment a plurality of moveable parts 50 are positioned at a same radial distance from the center 30.

In an embodiment the position of the moveable part 50 in the retracted position is passively controlled. For example in an embodiment the position of the moveable part 50 is controlled by an abutment between the moveable part 50 and the main body 22 (e.g. with a seal 60, such as illustrated in FIG. 3) such that the upper surface of the moveable part 50 is substantially co-planar with the support surface 20.

In an embodiment the position of the moveable member 50 is actively controlled in the retracted position. In an embodiment a positioning device, sensor and controller are provided for that purpose. For example active servo positioning may be used to control the position of the moveable part 50 such that its top surface is in substantially the same plane as the support surface 20. In an embodiment the active control is achieved by an abutment of the moveable part 50 with a piezoelectric element (e.g. a seal 60).

In an embodiment the moveable part 50 is made of the same material as the main body 22. In an embodiment the material of the moveable part 50 is SiSiC.

In FIG. 4 the moveable part 50 is in the extended position during loading or unloading of the substrate W. In this position the substrate W is supported only by the moveable part of the support surface 20.

In an embodiment the moveable part 50 may be provided with one or more heaters and/or coolers to thermally condition the moveable part 50. As can be seen from FIG. 3 the moveable part 50 is separated from the remainder of the support 1 (i.e. the main body 22). Therefore, the moveable part 50 is thermally isolated from the remainder of the support 1. As a result, the moveable member 50 may have a different temperature to the remainder of the support 1. This can lead to undesirable heat transfer to/from the substrate W through the moveable part of the support surface 20 and thereby localized heating or cooling of the substrate W. Such localized heating or cooling of the substrate W may lead to overlay errors. In an embodiment one or more heaters and/or coolers are provided in the moveable part 50. The one or more heaters and/or coolers are controlled to apply/remove a heat load to the moveable part 50 to bring its temperature substantially equal to that of the remainder (e.g. main body 22) of the support 1. In this way localized heating/cooling effects achieved through heat transfer through the moveable part of the support surface 20 can be reduced, minimized or even avoided. In an embodiment a conduit is provided in the moveable part 50 for the passage therethrough of a temperature conditioned fluid for the same purpose.

The support 1 may clamp the substrate in position on the support surface 20. This may be performed in any way. The embodiment of FIG. 3 illustrates one example of how this can be achieved using a vacuum. An underpressure is created in the space between the substrate W, projections and an upper surface 25 of the main body 22 of the support 1. Because the moveable part 50 is separate from the main body 22 of the support 1, a gap between the moveable part 50 and main body 22 is sealed when the moveable part 50 is in the retracted position. This can be achieved by providing seal 60, between the moveable part 50 and the main body 22, attached to one or the other. The seal 60 may be a contactless seal meaning that a small gap (a few μm) exists between the seal 60 and the moveable part 50, even in the retracted position. The seal 60 provides a resistance to the passage of gas between the moveable part 50 and the main body 22 so that an underpressure can build up and be sustained between the substrate W and the top surface 25 of the main body. The distance between the seal 60 and the moveable part 50 is kept low (of the order of 1 or 2 μm) and this helps ensure that a suitable level of vacuum can still be achieved in the space between the substrate W, top surface 25 of the main body 22 and burls. A contactless seal 60 has an advantage of not forcing a position on the moveable part 50 and/or minimizing contamination sensitivity. Contamination of a contacting seal could lead to positional inaccuracy of the moveable part 50.

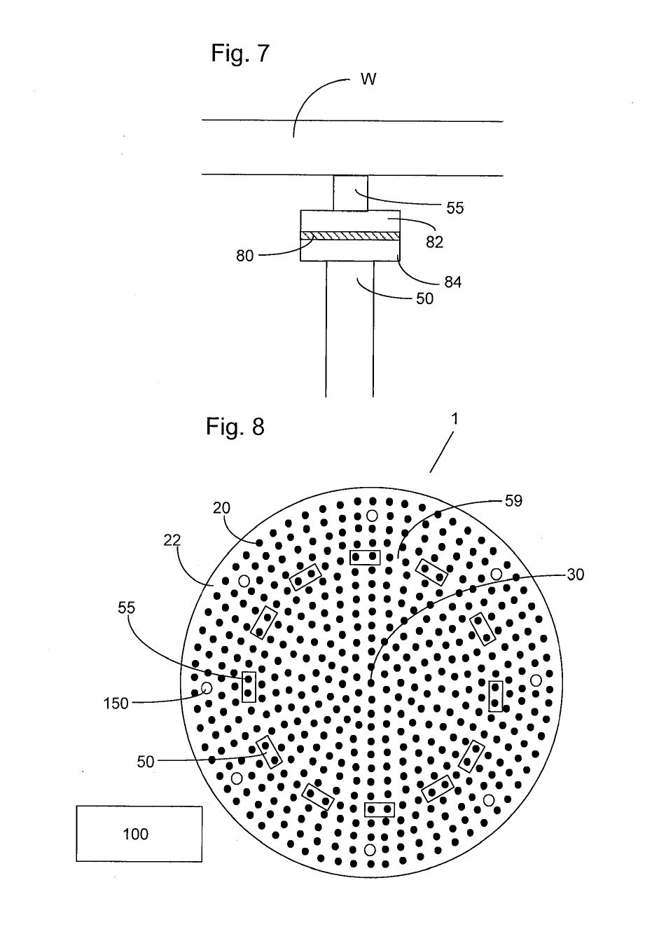

In the case of the support 1 being an electrostatic clamp, no seal 60 may need to be provided but a seal might be present as a positioning feature (passive or active) for the moveable part 50. It may be desirable to help ensure that an electrostatic clamping force is present between the moveable part 50 and substrate W to ensure uniformity of clamping and/or clamping during loading and unloading. This can be achieved in the same way as elsewhere in the main body 22. An example of how this is achieved is illustrated in FIG. 7.

It may be desirable to apply a clamping force between the substrate W and the moveable part 50 when the moveable part 50 is in the extended position or in any other position. Additionally, as described above, it may be advantageous that a force is applied between the moveable part 50 and the substrate W even when the moveable part 50 is in the retracted position, particularly in the case where the support 1 is an electrostatic clamping support. In this case the method of achieving a force between the moveable part 50 and the substrate W as illustrated in FIG. 7 can be used both in the retracted position and the extended position of the moveable part 50 and any position between those two positions.

FIGS. 5 and 6 illustrate the way in which a clamping force can be applied between the moveable part 50 and the substrate W in the extended position (and in any other position) for a vacuum clamp. This is achieved by providing a ridge 70 on the moveable part 50. The ridge 70 has an upper surface which is lower than the moveable part of the support surface 20 (i.e. the top of projection 55). In this way there is no contact between the ridge 70 and the substrate W. An opening 71 is provided in fluid contact with an area surrounded by the ridge 70. A vacuum source, for example a chamber 72 formed in the body of the moveable part 50, is connected to an underpressure source through a conduit 73 in the elongate member 57. In this way an underpressure can be created between the ridge 70 and the substrate W to attract the substrate W towards the moveable part 50. As is illustrated in FIG. 2 and in more detail in FIG. 6, the presence of a ridge 70 may take the place of a burl (projection) which otherwise may be present in that location. For this reason only a few ridges 70 may be provided around the multi-sided shape. The ridge 70 does not touch the substrate W to avoid contamination and thereby possible unflatness caused by contamination. The elongate member 57 (of which there are a few around the periphery of the moveable part 50, for example three) is used to move the moveable part 50 as well as to provide the conduit 73.

FIG. 7 illustrates how an attractive force may be provided between the moveable part 50 and the substrate W in an electrostatic support 1. In this embodiment an electrode 80 is provided in the moveable part 50 between a dielectric layer 82 and an isolator layer 84. The electrode 80 may have a positive or negative voltage applied such that an electrostatic clamping force is generated between the substrate W and the electrode 80 thereby drawing the substrate W onto the moveable part 50.

In an embodiment the clamping force between the substrate W and the moveable part 50 is applied during loading and unloading of the substrate W. A controller 100 may be provided to activate/deactivate the clamping force.

FIG. 8 illustrates an embodiment which is the same as the embodiment of FIG. 2 except as described below. Embodiments are possible in which all or only some of the differences between the embodiments of FIGS. 2 and 8 are implemented.

In an embodiment a plurality of one or more further moveable parts 150 may be provided. The moveable parts 150 may be the same as e-pins in that in a retracted position they do not contact the substrate W or may be the same as the moveable part 50 described above. In an embodiment the further moveable parts 150 are a plurality of discrete moveable parts 150. The further moveable parts 150 may be positioned radially inwardly, radially outwardly, or both, of the moveable part 50.

In an embodiment there are a plurality of moveable parts 50. The moveable parts 50 may be elongate. In an embodiment the plurality of moveable parts 50 may form the sides of a multi-sided shape, as illustrated in FIG. 8. The plurality of moveable parts 50 may form segments of that shape. There may be gaps 59 between adjacent moveable parts 50. In order that the presence of gaps 59 does not result in bending of the substrate W, in an embodiment the total length of the gaps 59 between adjacent moveable parts 50 of the multisided shape is less than 50% of the outer periphery of the multi-sided shape formed, in plan, by the plurality of moveable parts 50.

The support 1 may form part of a substrate table WT. Such a substrate table WT may be used in a lithographic apparatus, for example a projection lithographic apparatus.

A lithographic apparatus comprising a support 1 according to an embodiment of the present invention may comprise a substrate handler 600 to load and/or unload a substrate onto the support 1. Such a substrate handler 600 may have two arms which support the substrate W from underneath. The arms may support the substrate W at areas which, when the substrate W is loaded on the support, are outside of the moveable part 50. Additionally or alternatively one or more arms of the substrate handler 600 may support the substrate W at a position of equal radius or lower radius than the position of the moveable part 50. This could be achieved in the embodiment of FIG. 8 if the arms of the substrate handler 600 could be inserted between the moveable parts 50 through the gaps 59 and/or one or more moveable parts 50 could be moved from the extended position to allow the arms under the substrate W at the appropriate position.

In an embodiment the substrate handler 600 may handle the substrate from above. In an embodiment the substrate handler 600 may handle the substrate from above by edges of the substrate. In an embodiment, a holding mechanism of the substrate handler 600 can comprise a plurality of brackets arranged to support the substrate W along the edge of the substrate W. In such an embodiment, the brackets can be arranged to move outwardly and inwardly to retrieve and release the substrate W. In order to allow such displacement, the holder can be provided with one or more actuators such as piezo-electric or electromagnetic actuators. Such an embodiment is described in U.S. patent application no. U.S. 61/552,282, filed on 27 Oct. 2011, herein incorporated in its entirety by reference.

In an embodiment, there is provided a support for an object, comprising: a support surface configured to support the object; wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.

In an embodiment, the moveable part of the support surface is an upper end of a moveable part. In an embodiment, the moveable part of the support surface is arranged, in plan, to form the sides of a multi-sided shape.

In an embodiment, there is provided a support for an object, comprising: a support surface configured to support the object; and an elongate moveable part arranged, in plan, to form a side of a multi-sided shape and moveable between a retracted position in which an upper end of the moveable part is adapted to be at or below the plane of a main part of the support surface and an extended position in which the upper end of the moveable part protrudes from the plane of the main part of the support surface.

In an embodiment, the retracted position, the upper end of the moveable part forms a moveable part of the support surface and is adapted to be in substantially the same plane as the main part of the support surface which comprises the remainder of the support surface. In an embodiment, the multi-sided shape comprises at least eight sides. In an embodiment, the multi-sided shape is substantially a circle. In an embodiment, the multi-sided shape is substantially a gapless complete shape. In an embodiment, the multi-sided shape is formed by a plurality of moveable segments. In an embodiment, the segments are separated by gaps and the sum of the length of gaps between adjacent segments is less than 50% of the outer periphery of the multi-sided shape. In an embodiment, each moveable part, in plan, is in the shape of an arc. In an embodiment, the support surface is formed of a plurality of upper ends of discrete projections. In an embodiment, the moveable part is fewer than five projections wide, fewer than three projections wide, fewer than two projections wide or one projection wide. In an embodiment, the moveable part comprises a ridge which is lower than the projections. In an embodiment, the support further comprises a conduit in fluid communication with an area surrounded by the ridge and connectable to an underpressure source. In an embodiment, in plan, the moveable part is elongate. In an embodiment, the moveable part is positioned a constant radial distance from a center of the support surface. In an embodiment, the moveable part is positioned such that a size of an area of the support surface surrounded by the moveable part is within 20% of a size of an area of the support surface not surrounded by the moveable part. In an embodiment, the area, in plan, of the moveable part is at least 0.3% of the area of the support surface, in plan, at least 0.5% of the area of the support surface, in plan, or at least 0.8% of the area of the support surface, in plan. In an embodiment, the support further comprises a seal to resist passage of gas between the moveable part and the support surface when the moveable part is in the retracted position. In an embodiment, the support further comprises a heater and/or cooler to heat and/or cool the moveable part. In an embodiment, the support further comprises a further moveable part positioned at a radial distance from a center of the support surface different to that of the moveable part. In an embodiment, the support is configured to use an underpressure to clamp the object to the support surface. In an embodiment, the support is configured to clamp the object to the support surface with an electrostatic force. In an embodiment, the support is configured to support a substrate in a lithographic apparatus. In an embodiment, the support further comprises a controller configured to actively position the moveable part when in the retracted position.

In an embodiment, there is provided a lithographic apparatus comprising the support as described herein. In an embodiment, the lithographic apparatus further comprises a handler to position the object on the support surface. In an embodiment, the handler is arranged to grip the object from above. In an embodiment, the handler is configured to grip the object at its edge.

In an embodiment, there is provided a device manufacturing method comprising projecting a patterned beam of radiation onto a substrate supported by a support surface, wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains one or multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 436, 405, 365, 355, 248, 193, 157 or 126 nm) and extreme ultra-violet (EUV) radiation (e.g. having a wavelength in the range of 5-20 nm), as well as particle beams, such as ion beams or electron beams.

While specific embodiments of the invention have been described above, it will be appreciated that the invention may be practiced otherwise than as described. For example, the embodiments of the invention may take the form of a computer program containing one or more sequences of machine-readable instructions describing a method as disclosed above, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

An embodiment of the invention may be applied to substrates with a diameter of 300 mm, 450 mm or any other size.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include a data storage medium or data storage media for storing such computer programs, and/or hardware to receive such a medium/media. So the controller(s) may operate according the machine readable instructions of one or more computer programs.

One or more embodiments of the invention may be applied to any immersion lithography apparatus, whether the immersion liquid is provided in the form of a bath, only on a localized surface area of the substrate, or is unconfined. In an unconfined arrangement, the immersion liquid may flow over the surface of the substrate and/or substrate table so that substantially the entire uncovered surface of the substrate table and/or substrate is wetted. In such an unconfined immersion system, the liquid supply system may not confine the immersion liquid or it may provide a proportion of immersion liquid confinement, but not substantially complete confinement of the immersion liquid.

In an embodiment, the lithographic apparatus is a multi-stage apparatus comprising two or more tables located at the exposure side of the projection system, each table comprising and/or holding one or more objects. In an embodiment, one or more of the tables may hold a radiation-sensitive substrate. In an embodiment, one or more of the tables may hold a sensor to measure radiation from the projection system. In an embodiment, the multi-stage apparatus comprises a first table configured to hold a radiation-sensitive substrate (i.e., a substrate table) and a second table not configured to hold a radiation-sensitive substrate (referred to hereinafter generally, and without limitation, as a measurement and/or cleaning table). The second table may comprise and/or may hold one or more objects, other than a radiation-sensitive substrate. Such one or more objects may include one or more selected from the following: a sensor to measure radiation from the projection system, one or more alignment marks, and/or a cleaning device (to clean, e.g., the liquid confinement structure).

In an embodiment, the lithographic apparatus may comprise an encoder system to measure the position, velocity, etc. of a component of the apparatus. In an embodiment, the component comprises a substrate table. In an embodiment, the component comprises a measurement and/or cleaning table. The encoder system may be in addition to or an alternative to the interferometer system described herein for the tables. The encoder system comprises a sensor, transducer or readhead associated, e.g., paired, with a scale or grid. In an embodiment, the movable component (e.g., the substrate table and/or the measurement and/or cleaning table) has one or more scales or grids and a frame of the lithographic apparatus with respect to which the component moves has one or more of sensors, transducers or readheads. The one or more of sensors, transducers or readheads cooperate with the scale(s) or grid(s) to determine the position, velocity, etc. of the component. In an embodiment, a frame of the lithographic apparatus with respect to which a component moves has one or more scales or grids and the movable component (e.g., the substrate table and/or the measurement and/or cleaning table) has one or more of sensors, transducers or readheads that cooperate with the scale(s) or grid(s) to determine the position, velocity, etc. of the component.

The term “lens”, where the context allows, may refer to any one or combination of various types of optical components, including refractive, reflective, catadioptric, magnetic, electromagnetic and electrostatic optical components.

The descriptions above are intended to be illustrative, not limiting. Thus, it will be apparent to one skilled in the art that modifications may be made to the invention as described without departing from the scope of the claims set out below.

1. A support for an object, comprising:
a support surface configured to support the object;
wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.

2. The support of claim 1, wherein the moveable part of the support surface is an upper end of a moveable part.

3. The support of claim 1, wherein the moveable part of the support surface is arranged, in plan, to form the sides of a multi-sided shape.

4. The support of claim 3, wherein the multi-sided shape comprises at least eight sides.

5. The support of claim 4, wherein the multi-sided shape is substantially a circle.

6. The support of claim 3, wherein the multi-sided shape is substantially a gapless complete shape.

7. The support of claim 3, wherein the multi-sided shape is formed by a plurality of moveable segments.

8. The support of claim 1, wherein each moveable part, in plan, is in the shape of an arc.

9. The support of claim 1, wherein the support surface is formed of a plurality of upper ends of discrete projections and the moveable part is fewer than five projections wide.

10. The support of claim 1, wherein the support surface is formed of a plurality of upper ends of discrete projections and the moveable part comprises a ridge which is lower than the projections.

11. The support of claim 1, wherein the moveable part is positioned a constant radial distance from a center of the support surface.

12. The support of claim 1, wherein the moveable part is positioned such that a size of an area of the support surface surrounded by the moveable part is within 20% of a size of an area of the support surface not surrounded by the moveable part.

13. The support of claim 1, wherein the area, in plan, of the moveable part is at least 0.3% of the area of the support surface, in plan.

14. The support of claim 1, further comprising a seal to resist passage of gas between the moveable part and the support surface when the moveable part is in the retracted position.

15. The support of claim 1, further comprising a heater and/or cooler to heat and/or cool the moveable part.

16. The support of claim 1, further comprising a further moveable part positioned at a radial distance from a center of the support surface different to that of the moveable part.

17. The support of claim 1, further comprising a controller configured to actively position the moveable part when in the retracted position.

18. A support for an object, comprising:
a support surface configured to support the object; and
an elongate moveable part arranged, in plan, to form a side of a multi-sided shape and moveable between a retracted position in which an upper end of the moveable part is adapted to be at or below the plane of a main part of the support surface and an extended position in which the upper end of the moveable part protrudes from the plane of the main part of the support surface.

19. The support of claim 18, wherein, in the retracted position, the upper end of the moveable part forms a moveable part of the support surface and is adapted to be in substantially the same plane as the main part of the support surface which comprises the remainder of the support surface.

20. A device manufacturing method comprising projecting a patterned beam of radiation onto a substrate supported by a support surface, wherein the support surface includes a main part and a moveable part, the moveable part of the support surface being moveable between a retracted position in which the moveable part of the support surface is adapted to be substantially in the same plane as the main part of the support surface and an extended position in which the moveable part of the support surface protrudes from the plane of the main part of the support surface.
